(19) United States
(12) Patent Application Publication
(10) Pub. No.: US 2016/0043074 A1
(43) Pub. Date: Feb. 11, 2016

(54) JUNCTIONLESS NANOWIRE TRANSISTORS FOR 3D MONOLITHIC INTEGRATION OF CMOS INVERTERS

(71) Applicant: UNIVERSITY COLLEGE CORK - NATIONAL UNIVERSITY OF IRELAND, CORK, Cork City (IE)

(72) Inventors: Paul HURLEY, Douglas, Cork (IE); Karim CHERKAOUI, Douglas, Cork (IE); Vladimir DJARA, Cork (IE)

(73) Assignee: University College Cork - National University of Ireland, Cork, Cork City (IE)

(21) Appl. No.: 14/782,570

(22) PCT Filed: Apr. 7, 2014
(86) PCT No.: PCT/EP2014/056959

§ 371 Date: Oct. 5, 2015

(30) Foreign Application Priority Data
Apr. 5, 2013 (EP) 13162474.4

(51) Int. Cl. H01L 27/06; H01L 21/84; H01L 29/16; H01L 27/12; H01L 29/06; H01L 29/20; H01L 21/8258; H01L 27/092

(52) U.S. Cl. CPC H01L 27/0688; H01L 21/8258; H01L 21/84; H01L 27/0605; H01L 27/092; H01L 27/1203; H01L 29/0673; H01L 29/20; H01L 29/16

(57) ABSTRACT

The invention provides a three dimensional (3D) semi-conductor device comprising a first junctionless transistor doped with dopants of the same polarity; a second junctionless transistor doped with dopants of the same polarity; and the second junctionless transistor and the first junctionless transistor comprise an opposite dopant polarity are stacked in a vertical arrangement, where the first and second junctionless transistors are separated by an insulating layer. The invention makes use of the fact that the transistors are uniformly doped with the same polarity to provide a junctionless transistor. The junctionless concept provides that the junction is already formed, so there is no high temperature step associated with junction formation or junction regrowth. This is an important advantage in the junctionless concept in relation to 3D monolithic integration that allows for vertical stacking of the transistors to form a three dimensional CMOS inverter.

### FIELD

The invention relates to a metal-oxide-semiconductor (MOS) transistor based inverter design.

### BACKGROUND

The principal driver for the mainstream high performance semiconductor industry is the scaling of the minimum dimensions of metal oxide semiconductor field effect transistors (MOSFETs), which constitute the fundamental switching elements of integrated circuits. The scaling of MOSFET dimensions from values of around 10 μm in the early 1970's to values of around 22 nm in early 2013 has enabled the dramatic developments in computing power, information storage and digital communication technologies. The scaling of device dimensions and the associated increase in MOSFET density has consequences for integrated circuit power dissipation.

As the size of individual transistors in integrated circuits reach the limits of dimensional scaling, one avenue of future research is focussing on three dimensional (3D) monolithic integration, where devices are stacked on top of each other. For example, where one transistor in an inverter is fabricated on top of a complementary transistor. This has the potential to increases the transistor density per unit area, without further scaling of the minimum channel length of the MOS transistor.

Three dimensional (3D) integration offers a route to reduce the unit area occupied by logic circuits, with the potential for up to 50% reduction in “plan view” area density.

One of the main problems with 3D integration is the reduced thermal budget imposed on the transistors in the 2^{nd} and any subsequent layers on the 3D monolithic integration. The top layer thermal budget is constrained by the maximum thermal budget of the previous layer or layers. This makes transistor source and drain formation particularly challenging for monolithic 3D integration with implanted and thermally activated source and drain regions or using source and drain regrowth, as both of these processes are high temperature (typically >600° C.). A further problem with 3D integration is that each layer must be formed by sequential processing followed by wafer bonding, with associated alignment challenges between the various layers in the 3D structure. Another problem is that 3D integration may also increase the number of critical layers for lithography.

US Patent Publication number US2011/121366, OR-BACH ZVI et al discloses a semiconductor device includes a first single crystal silicon layer including first transistors, a first alignment mark, and at least one metal layer overlying the first single crystal silicon layer for interconnecting the first transistors. In a 3D inverter cell such as described in this US publication, the source and drain regions are formed prior to the stacking of transistors. This means the transistors need to be aligned prior to bonding. This very complex step is exacerbated when transistor dimensions are small. The bonded layer must be aligned to these predefined structures which make this process extremely difficult.

Japanese Patent Publication number JP 2007 250652, Sharp K K et al, discloses a semiconductor device with a logical circuit constituted therein, which includes: an inverter, a NAND, a NOR, an AND, an OR, or the combination of them, while taking advantage of the characteristics of a transistor with a three-dimensional structure formed on the side wall of an island shape semiconductor layer. However this Japanese publication places the transistors side by side and uses conventional MOSFET devices, making the device complex and difficult to make especially at smaller geometries.

It is therefore an object of the invention to provide a three dimensional (3D) configuration of semi-conductor devices to overcome one or more of the above mentioned problems with current routes to 3D monolithic integration.

### SUMMARY

According to the invention there is provided, as set out in the appended claims, a three dimensional (3D) semi-conductor device comprising:
a first junctionless transistor doped with dopants of the same polarity;
a second junctionless transistor doped with dopants of the same polarity; and
the second junctionless transistor and the first junctionless transistor comprise an opposite dopant polarity and are stacked in a substantially vertical arrangement, where the first and second junctionless transistors are separated by an insulating layer.

The invention makes use of the fact that the transistors are uniformly doped with the same polarity to provide a junctionless transistor. The junctionless concept provides that the junction is already formed, so there is no high temperature step associated with junction formation or junction regrowth. This is an important advantage in the junctionless concept in relation to 3D monolithic integration that allows for vertical stacking of the transistors to form a three dimensional semi-conductors and associated circuits.

An advantage of the present invention is the gain from simplification in critical lithography steps as the full inverter is self-aligned. This very complex step associated with the prior art is not required to fabricate the 3D inverter with junctionless transistors of the current invention. This combination also gives benefits in terms of thermal budget reduction. The geometry of the 3D structure combined with the unique bulk transport properties of the juctionless also enables the increase of drain current from increasing the layer thickness without increasing the full inverter footprint; this will also help to reduce the source and drain contact resistance.

A further advantage of the junctionless MOSFET in 3D monolithic integration relates to the number of critical lithography steps. The definition of the MOSFET with the minimum gate length and minimum gate width represents one of the critical lithography steps.

In one embodiment of the invention, as the devices are junctionless, a single lithography and etch step can be used to define the minimum feature size in two or more layers of the 3D structure, hence reducing the number of critical lithography steps needed for 3D monolithic integration.

In one embodiment there is provided an insulator material between the first junctionless transistor and the second junctionless transistor.

In one embodiment the first junctionless transistor is doped with a N type material.

In one embodiment the second junctionless transistor is doped with a P type material.

In one embodiment the first transistor comprises one or more of the following: Si, Ge, SiGe, SiC, GaAs, InGaAs, InAs, InP, GaN, GaSb, InGaSb, GeSn; semi metals, graphene and other 2D materials such as MoS₂, MoSe₂, WS₂, WSe₂, TiS₂ and TiSe₂. These semiconductor and semi-metal layers can be in a crystalline, polycrystalline or amorphous form.

In one embodiment the first transistor comprises a heavily N type doped InGaAs layer.

In one embodiment the second transistor comprises Ge or Si or SiGe and the first transistor comprises InGaAs, wherein the InGaAs (n) layer and the Ge (p) or Si or SiGe (p) layer are etched in one step to form said 3D semiconductor device.

In one embodiment the junctionless stacked transistors comprises a vertically stacked CMOS inverter.

In another embodiment there is provided a 3D semiconductor device comprising a high mobility N type transistor layer on a substrate overlaid with a dielectric layer and a high mobility P type transistor layer.

In another embodiment of the invention there is provided a 3D semiconductor device comprising a high mobility P type transistor layer on a substrate overlaid with a dielectric layer and a high mobility N type transistor layer.

In a further embodiment of the invention there is provided a process for making a three dimensional (3D) CMOS inverter comprising the steps of:
forming at least one junctionless transistor on a first layer;
applying an insulating layer on the first layer;
forming at least one junctionless transistor on a second layer on top of said insulating layer, wherein said first, insulating and second layers are defined in a single etching step.

The invention provides a number of advantages:
A number of the transistor processing steps can be run in parallel. Current 3D integration of devices, such as a CMOS inverter, is sequential.
Current 3D integration methods must be able to align fully processed devices from one level to the next. In the inventive process, the two stacked transistors are self-aligned. The two transistors can be defined during a single process step.
In conventional CMOS inverters, the pFET width is usually much larger than the nFET to match the current drive of each transistor, due to the differences in the mobility values of electrons and holes. 3D integration using junctionless transistors enables this transistor matching to be achieved by an increased thickness of the pFET layer as opposed to the device width, and as a consequence the footprint of the two transistor types remains identical.
The contact resistance to the source and drain regions can be reduced by increasing the height of the device, such that the contact resistance can be reduced without consuming more planar area.
The crystalline orientation of a second layer with respect to the first semiconductor layer can be selected to maximise the mobility in the direction of current flow.

In one embodiment the process comprises the step of aligning the first and second layers during the single etching step.

In one embodiment the process comprises the step of using a low temperature step for said second layer and subsequent layers.

In one embodiment the process comprises the step of increasing the height of the device, such that the contact resistance can be reduced without consuming planar area of the 3D semiconductor device.

In one embodiment the process comprises the step of orientating second layer with respect to the first semiconductor layer to maximise the mobility in the direction of current flow.

In one embodiment the process comprises the step of orientating the crystalline structure of the second layer with respect to the first layer.

In one embodiment the 3D semiconductor device comprises a stacked CMOS inverter device.

In one embodiment the insulator layer comprises an oxide material.

### BRIEF DESCRIPTION OF THE DRAWINGS

The invention will be more clearly understood from the following description of an embodiment thereof, given by way of example only, with reference to the accompanying drawings, in which:

FIG. 1 illustrates a plan view of a conventional CMOS inverter;

FIG. 2 illustrates a wafer cross section according to one embodiment of the invention showing a high mobility N type semiconductor layer on a substrate overlaid with a dielectric layer and a high mobility P type semiconductor layer. It is noted that the device can also be realised with the first layer as a high mobility P type semiconductor and the second layer as a high mobility N type semiconductor;

FIG. 3 illustrates a 3D perspective view of FIG. 2;

FIG. 4 illustrates a three dimensional (3D) semi-conductor device in the form of a CMOS inverter according to one embodiment of the invention; and illustrates the ground (GND), input voltage (IN), supply voltage (VDD), output voltage (OUT) of the CMOS inverter. Note how the source of the junctionless P channel MOSFET and the drain of the N channel junctionless MOSFET are connected to form the CMOS inverter output;

FIG. 5 illustrates a three dimensional (3D) semi-conductor device showing the two junctionless semiconductor MOSFETs, stacked on top of each other, according to one embodiment of the invention; and

FIG. 6 illustrates a cross section view of the 3D semi-conductor device of FIG. 5.

### DETAILED DESCRIPTION OF THE DRAWINGS

According to one aspect the invention provides a three dimensional (3D) semi-conductor device comprising a first junctionless transistor doped with dopants of the same polarity; a second junctionless transistor doped with dopants of the same polarity; and the second junctionless transistor and the first junctionless transistor comprise an opposite dopant polarity and are stacked in a substantially vertical arrangement.

The concept of the junctionless nanowire transistor, for example a MOSFET transistor, in silicon has already been demonstrated experimentally, and details can be found in a Nature paper published by Jean-Pierre Colinge, Chi-Woo Lee, Aryan Afzalian, Nima Dehdashti Akhavan, Ran Yan, Isabelle Ferain, Pedram Razavi, Brendan O'Neill, Alan Blake, Mary White, Anne-Marie Kelleher, Brendan McCarthy and Richard Murphy, “Nanowire Transistors without Junctions”, Nature Nanotechnology 5, 225-229 (2010) and related PCT patent publication number WO 20100025938 entitled Junctionless Metal-Oxide-Semiconductor Transistor and is incorporated herein by reference.

One of the main barriers to 3D integration is the low thermal budget imposed on the transistors in the second and subsequent layers of the 3D monolithic integrated circuits. The high temperature step needed in traditional devices is the activation of dopants in the source and drain regions of the MOSFET. The junctionless concept applied to 3D monolithic integration does not need a high temperature as there is no junction thermal activation anneal.

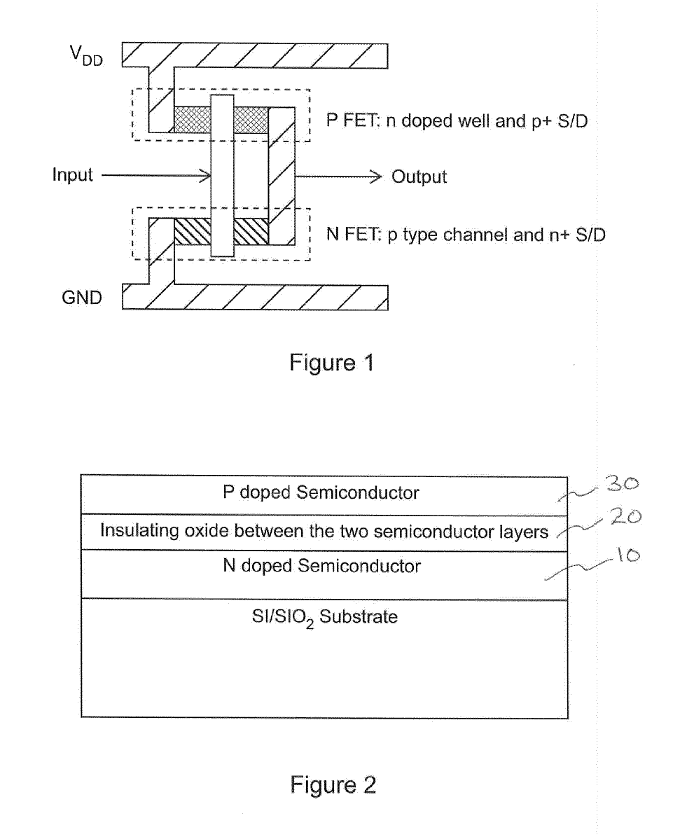

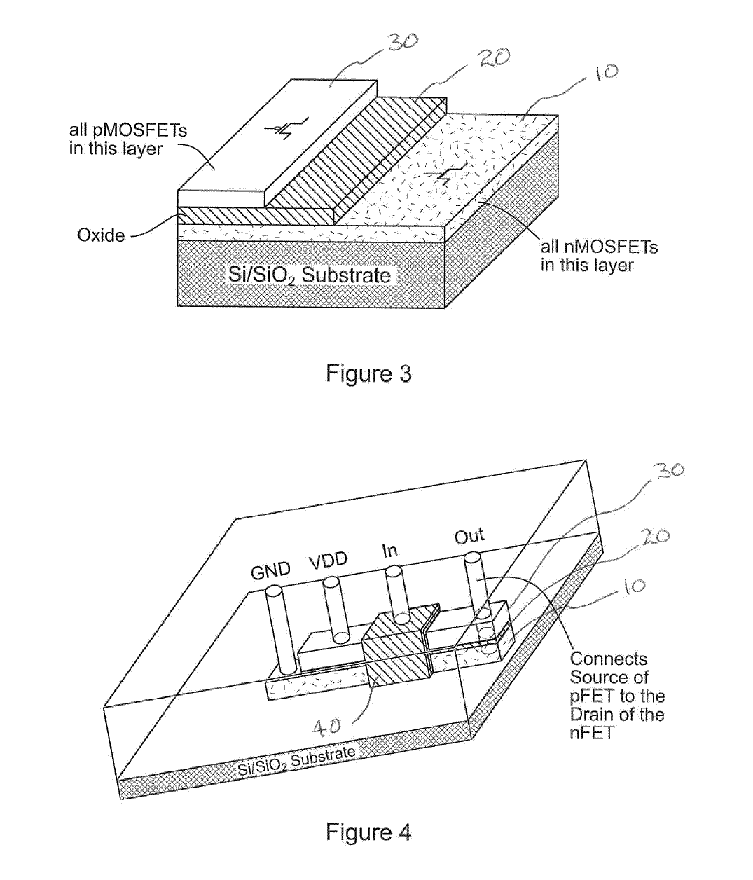

FIG. 1 illustrates a conventional CMOS inverter in plan view. FIGS. 2 & 3 illustrates a wafer cross section according to one embodiment of the invention showing a high mobility N type junctionless transistor layer 10 on a substrate overlaid with a dielectric layer (20) and a high mobility P type junctionless transistor layer (30). The dielectric layer (20) is an insulator material, for example an oxide material.

As the junctions are in place, the invention only requires one critical layer for lithography. For example, if the MOSFET n channel device was formed in InGaAs and the p channel device was formed in Ge. The InGaAs (n) layer and the Ge (p) layers are etched in one step. The gate oxide is then grown all around the structure by atomic layer deposition. This also simplifies the connecting approach of the different gate electrodes of the n and the p channel MOSFETs of the logic inverter.

FIG. 4 illustrates a three dimensional (3D) semi-conductor device in the form of a CMOS inverter according to one embodiment of the invention. In this simplified schematic of the inverter the first and second junctionless transistors are simply drawn as two stacked parallelepipeds separated by an insulator. In the channel region of both transistors a gate oxide (40) is wrapped around both transistors. The gate electrode is formed on the top of the gate oxide.

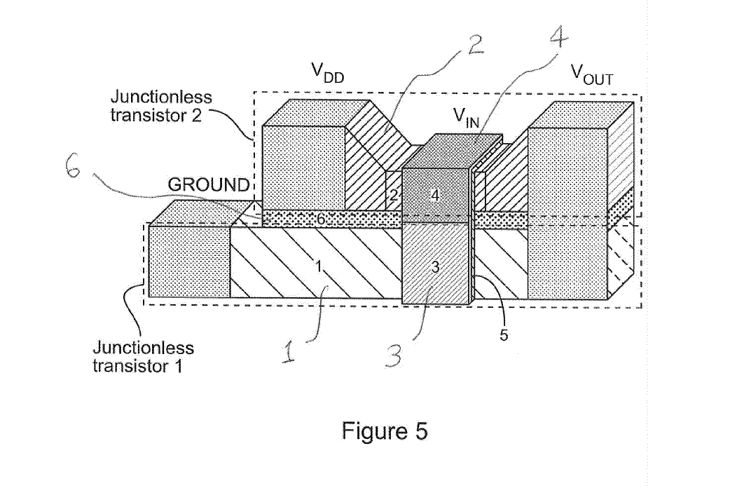

FIG. 5 illustrates another representation of the three dimensional (3D) semi-conductor device showing two junctionless transistors in a 3D arrangement. The uniformly doped semiconductor forming a first junctionless transistor (1) positioned at the base of the 3D inverter. A layer (6) provides insulation between the first junctionless transistor (1) and a second junctionless transistor (2). A gate oxide (5) common to both transistors is wrapped around a channel area of (1) and (2). A gate (3) of junctionless transistor (1) is engineered to deplete the channel (1) when a gate (4) is keeping the junctionless transistor (2) on.

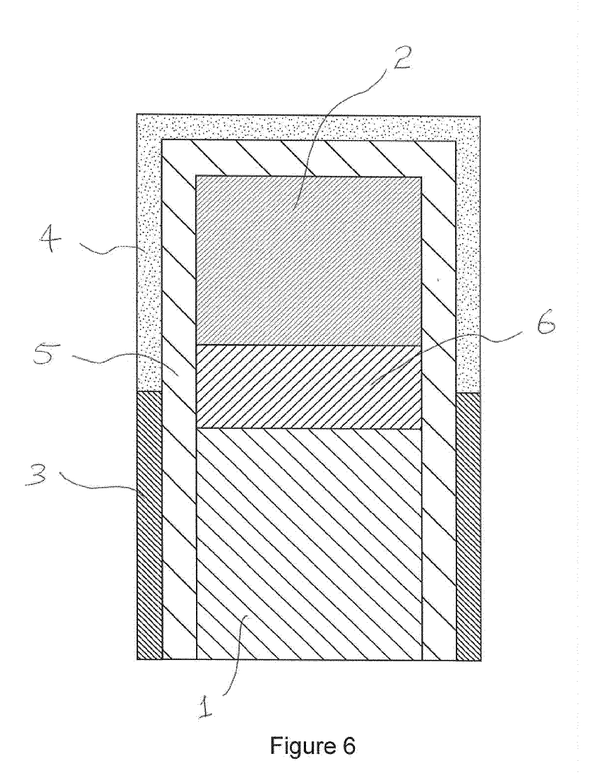

FIG. 6 illustrates a cross section of the device of FIG. 5 showing how the gate oxide wraps (5) around the two channels and showing the arrangement of the two different metal gates for the two transistors (1, 2).

The inventors discovered that the use of stacked layers of junctionless transistors provides an effective means to make 3D vertical semiconductor devices, such as CMOS inverters. The use of III-V materials in future n channel transistors is driven by the potential to reduce power consumption in future integrated circuits. It is clear from the current literature, that one of the major obstacles for high mobility compound semiconductor MOSFETs is the source and drain formation. As a consequence, the junctionless device concept initially developed for silicon MOSFETs is ideally suited for high mobility III-V MOSFETs, as it avoids source and drain implantation and dopant activation annealing, source and drain re-growth or the necessity to etch back through a barrier layer and etch stop on a narrow quantum well (QW) channel region. In short, it circumvents the source and drain formation problems.

For the junctionless device high doping is needed throughout the device both in the channel and in the source and drain. For silicon at doping levels in excess of 1×10¹⁹ cm⁻³, the electron mobility is relatively low at ˜100 cm²/Vs. This limits the drive current and also impacts on the source and drain resistance of silicon based junctionless MOSFETs.

For In_{0.53}Ga_{0.47}As the electron mobility for a doping concentration ˜2×10¹⁸ cm⁻³ is >4,000 cm²/Vs, which is 40 times higher than silicon. These mobility values are based on In_{0.53}Ga_{0.47}As samples grown and characterised, and are consistent with other published mobility data at high doping (˜4,000 cm²/Vs at 4×10¹⁸ cm⁻³). This has two significant advantages for the development of the junctionless In_{0.53}Ga_{0.47}As MOSFET, which are: (i) the electron mobility remains high even at the high doping levels needed in the channel, and (ii) the high mobility of ˜4,000 cm²/Vs at 4×10¹⁸ cm⁻³ minimises the access resistance of the source and drain regions.

In the small device cross sectional area of a nanowire transistor, the effect of quantum confinement is to move the peak carrier density away from the semiconductor dielectric interface, which is anticipated to improve drive current due to a reduction of scattering due to a range of factors, such as: surface roughness, high-k oxide charge and high-k remote phonon interaction. Moreover, the dimensions to observe quantum confinement effects is proportional to h²π²/2m*W², where m* is the effective mass of the electron in the semiconductor, W is the width of the device, and the other terms have their usual meanings. As the electron effective mass (mₑ) is considerably smaller in In_{0.53}Ga_{0.47}As (mₑ˜0.04 at x=0.53) compared to silicon (mₗ=0.92 m₀, mₜᵣ=0.19 m₀), the beneficial effects of quantum confinement should be observed at dimensions which are at least five times larger than in silicon devices. For silicon the effects are significant below 10 nm at 300K.

In the specification the terms “comprise, comprises, comprised and comprising” or any variation thereof and the terms include, includes, included and including” or any variation thereof are considered to be totally interchangeable and they should all be afforded the widest possible interpretation and vice versa.

The invention is not limited to the embodiments hereinbefore described but may be varied in both construction and detail.

1. A three dimensional (3D) semi-conductor device comprising:
a first junctionless transistor doped with dopants of the same polarity;
a second junctionless transistor doped with dopants of the same polarity; and
the second junctionless transistor and the first junctionless transistor comprise an opposite dopant polarity and are stacked in a substantially vertical arrangement, where the first and second junctionless transistors are separated by an insulating layer.

2. The 3D semiconductor device of claim 1 wherein the first and second junctionless transistors are aligned with respect to each other using a single etch process.

3. The 3D semiconductor device of claim 1 wherein the first junctionless transistor is doped either N type or P type.

4. The 3D semiconductor device of claim 1 wherein the second junctionless transistor is doped either P type or N type.

5. The 3D semiconductor device of claim 1 wherein the first junctionless transistor comprises one or more of the following: Si, Ge, SiGe, SiC, GaAs, InGaAs, InAs, InP, GaN, GaSb, InGaSb, GeSn; Semi-metals, graphene and other 2D materials such as MoS2, MoSe2, WS2, WSe2, TiS2 and TiSe2.

6. The 3D semiconductor device of claim 1 wherein the first junctionless transistor comprises a heavily N type doped InGaAs layer.

7. The 3D semiconductor device of claim 1 wherein the second junctionless transistor comprises Ge or Si or SiGe and the first transistor comprises InGaAs, wherein the InGaAs (n) layer and the Ge (p) or Si or SiGe (p) layer are etched in one step to form said 3D semiconductor device.

8. The 3D semiconductor device as claimed in claim 1 wherein the junctionless stacked transistors comprises a vertically stacked CMOS inverter.

9. A 3D semiconductor device comprising a high mobility N or P type junctionless transistor layer on a substrate overlaid with a dielectric layer and a high mobility P or N type junctionless transistor layer.

10. A process for making a three dimensional (3D) semiconductor device comprising the steps of:
forming at least one junctionless transistor on a first layer;
applying an insulating layer on the first layer;
forming at least one junctionless transistor on a second layer on top of said insulating layer, wherein said first, insulating and second layers are formed in a single etching step.

11. The process of claim 10 comprising the step of aligning the first and second layers during the single etching step.

12. The process of claim 10 comprising the step of using a low temperature step for said second layer and subsequent layers.

13. The process of any of claim 10 comprising the step of increasing the height of the device, such that the contact resistance can be reduced without consuming planar area of the 3D semiconductor device.

14. The process of any of claim 10 comprising the step of orientating second layer with respect to the first semiconductor layer to maximise the mobility in the direction of current flow.

15. The process of claim 14 wherein the step of orientating the crystalline structure of the second layer with respect to the first layer.
